(19) United States
(12) Patent Application Publication
(10) Pub. No.: US 2024/0154046 A1
(43) Pub. Date: May 9, 2024

(54) ELECTROMAGNETIC WAVE DETECTOR AND ELECTROMAGNETIC WAVE DETECTOR ARRAY

(71) Applicant: Mitsubishi Electric Corporation, Tokyo (JP)

(72) Inventors: Satoshi OKUDA, Chiyoda-ku, Tokyo (JP); Shimpei OGAWA, Chiyoda-ku, Tokyo (JP); Shoichiro FUKUSHIMA, Chiyoda-ku, Tokyo (JP); Masaaki SHIMATANI, Chiyoda-ku, Tokyo (JP)

(73) Assignee: Mitsubishi Electric Corporation, Tokyo (JP)

(21) Appl. No.: 18/280,674

(22) PCT Filed: Mar. 30, 2021
(86) PCT No.: PCT/JP2021/013671

§ 371 Date: Sep. 7, 2023

(51) Int. Cl. H01L 31/02; H01L 31/0224; H01L 31/0352

(52) U.S. Cl. CPC H01L 31/02005; H01L 31/022408; H01L 31/035272

(57) ABSTRACT

An electromagnetic wave detector includes a semiconductor layer, an insulating layer disposed on the semiconductor layer and having an opening, a two-dimensional material layer extending from on the opening to on the insulating layer, including a connection part in contact with a peripheral part of the insulating layer facing the opening, and electrically connected to the semiconductor layer, a first electrode part disposed on the insulating layer and electrically connected to the two-dimensional material layer, a second electrode part electrically connected to the semiconductor layer, and a unipolar barrier layer disposed between the semiconductor layer and the connection part of the two-dimensional material layer and electrically connected to each of the semiconductor layer and the two-dimensional material layer.

### TECHNICAL FIELD

The present disclosure relates to an electromagnetic wave detector, an electromagnetic wave detector array, and a method of manufacturing an electromagnetic wave detector.

### BACKGROUND ART

Graphene, which is an example of two-dimensional material layers and has extremely high mobility, has been known as a material of electromagnetic wave detecting layers for use in next-generation electromagnetic wave detectors. Furthermore, as the next-generation electromagnetic wave detector, an electromagnetic wave detector using a graphene field effect transistor is known in which monolayer or multilayer graphene is applied to the channel of a field effect transistor.

In a detector described in United States Patent Application Publication No. 2015/0243826 (PTL 1), in order to reduce dark current in a graphene field effect transistor, graphene formed to cover an opening is in direct contact with a silicon substrate in the opening formed in an insulating film covering a surface of the silicon substrate. In this detector, a Schottky barrier is formed at the interface between graphene sufficiently doped with an n-type or p-type impurity and a silicon substrate doped with a p-type or n-type impurity to produce a current rectifying effect.

In a detector described in WO2021/002070 (PTL 2), a two-dimensional material layer extends from on an opening formed in an insulating film covering a surface of a semiconductor layer to on the insulating film, and a pn junction is formed in the semiconductor layer immediately below the two-dimensional material layer positioned inside the opening. The semiconductor layer has a first semiconductor portion of a first conductivity type and a second semiconductor portion of a second conductivity type, and these portions form a pn junction. In the detector in PTL 2, formation of the pn junction produces a current rectifying effect. Further, in the detector in PTL 2, the pn junction functions as a photodiode, and when the pn junction interface is irradiated with an electromagnetic wave, a gate voltage is applied in a pseudo manner to the graphene through the insulating film to modulate the conductivity of the two-dimensional material layer. Consequently, photocurrent is amplified in the two-dimensional material layer.

### CITATION LIST

### Patent Literature

PTL 1: United States Patent Application Publication No. 2015/0243826
PTL 2: WO 2021/002070

### SUMMARY OF INVENTION

### Technical Problem

The density of states of a two-dimensional material such as graphene changes sensitively with the surrounding charges. For example, an electrical joint state between a two-dimensional material layer and a silicon substrate tends to change due to the effect of water adsorbed on the two-dimensional material layer or fixed charges of a protective film formed on the two-dimensional material layer. In the detector described in PTL 1, therefore, a sufficient height of the Schottky barrier may fail to be ensured, and as a result, electrons thermally excited in graphene may be emitted (thermionic emission) and injected into the silicon substrate across the Schottky barrier.

On the other hand, in the detector described in PTL 2, for example, when the conductivity type of the first semiconductor portion is p-type and the respective conductivity types of the two-dimensional material layer and the second semiconductor portion are n-type, an npn-type diode structure as shown in FIG. 21 is formed. In this case, when the semiconductor layer is irradiated with an electromagnetic wave such as light, holes produced in the depletion layer of the pn junction are extracted as photocurrent from the first electrode part through the two-dimensional material layer, but the extraction of holes is impeded by the barrier formed at the junction interface between the n-type two-dimensional material layer and the p-type first semiconductor portion. On the other hand, if a negative voltage applied to the pn junction of the n-type two-dimensional material layer and the p-type first semiconductor portion is increased in order to enhance the hole extraction efficiency, electrons thermally excited in the n-type two-dimensional material layer tend to flow into the p-type semiconductor layer to increase dark current.

A main object of the present disclosure is to provide an electromagnetic wave detector, an electromagnetic wave detector array, and a method of manufacturing an electromagnetic wave detector in which dark current can be reduced compared with conventional detectors without impeding extraction of photocarrier.

### Solution to Problem

An electromagnetic wave detector according to the present disclosure includes: a semiconductor layer; an insulating layer disposed on the semiconductor layer and having an opening; a two-dimensional material layer extending from on the opening to on the insulating layer, including a connection part in contact with a peripheral part of the insulating layer facing the opening, and electrically connected to the semiconductor layer; a first electrode part disposed on the insulating layer and electrically connected to the two-dimensional material layer; a second electrode part electrically connected to the semiconductor layer; and a unipolar barrier layer disposed between the semiconductor layer and the connection part of the two-dimensional material layer and electrically connected to each of the semiconductor layer and the two-dimensional material layer.

A method of manufacturing an electromagnetic wave detector according to the present disclosure includes the steps of: preparing a semiconductor layer; forming a unipolar barrier layer on the semiconductor layer; depositing an insulating layer on the semiconductor layer and the unipolar barrier layer; forming a second electrode part in contact with the semiconductor layer; forming a first electrode part on the insulating layer; partially removing the insulating layer disposed on the unipolar barrier layer to form an opening exposing the unipolar barrier layer in the insulating layer; and forming a two-dimensional material layer extending from on the unipolar barrier layer to the first electrode part through on the insulating layer.

### Advantageous Effects of Invention

The present disclosure can provide an electromagnetic wave detector, an electromagnetic wave detector array, and a method of manufacturing an electromagnetic wave detector in which dark current can be reduced compared with conventional detectors without impeding extraction of photocarrier.

### BRIEF DESCRIPTION OF DRAWINGS

FIG. 1 is a plan view of an electromagnetic wave detector according to a first embodiment.

FIG. 2 is a cross-sectional view as viewed from line II-II in FIG. 1.

FIG. 3 is an energy band diagram schematically showing a band structure along line A-B in FIG. 2.

FIG. 4 is an energy band diagram schematically showing a band structure in a modification of the electromagnetic wave detector according to the first embodiment.

FIG. 5 is a flowchart for explaining an exemplary method of manufacturing an electromagnetic wave detector according to the first embodiment.

FIG. 6 is an energy band diagram schematically showing a band structure in a modification of the electromagnetic wave detector according to the first embodiment.

FIG. 7 is an energy band diagram schematically showing a band structure in a modification of the electromagnetic wave detector according to the first embodiment.

FIG. 8 is a cross-sectional view of an electromagnetic wave detector according to a second embodiment.

FIG. 9 is an energy band diagram schematically showing a band structure along line A-B in FIG. 8.

FIG. 10 is an energy band diagram schematically showing a band structure in a modification of the electromagnetic wave detector according to the second embodiment.

FIG. 11 is a plan view of an electromagnetic wave detector according to a third embodiment.

FIG. 12 is a cross-sectional view as viewed from line XII-XII in FIG. 11.

FIG. 13 is a cross-sectional view of a modification of an electromagnetic wave detector according to a fourth embodiment.

FIG. 14 is a cross-sectional view of an electromagnetic wave detector according to a fifth embodiment.

FIG. 15 is a cross-sectional view of a modification of the electromagnetic wave detector according to the fifth embodiment.

FIG. 16 is a cross-sectional view of an electromagnetic wave detector according to a sixth embodiment.

FIG. 17 is a cross-sectional view of a modification of the electromagnetic wave detector according to the sixth embodiment.

FIG. 18 is a cross-sectional view of an electromagnetic wave detector according to a seventh embodiment.

FIG. 19 is a plan view of an electromagnetic wave detector array according to an eighth embodiment.

FIG. 20 is a plan view of a modification of the electromagnetic wave detector array according to the eighth embodiment.

FIG. 21 is an energy band diagram schematically showing the band structure of a detector having an npn-type diode structure, in which a semiconductor layer has a p-type first semiconductor portion and an n-type second semiconductor portion, and an n-type two-dimensional material layer is in contact with the first semiconductor portion.

### DESCRIPTION OF EMBODIMENTS

Embodiments of the present disclosure will be described below with reference to the drawings. The drawings are schematic and conceptually illustrate functions or structures. The present disclosure is not intended to be limited by the embodiments described below. The basic configuration of the electromagnetic wave detector is common in all the embodiments, unless otherwise specified. Those denoted by the same reference signs refer to the same or equivalent as described above. This applies in all the text in the description.

The wavelength band to be detected by the electromagnetic wave detector according to the present embodiment is not limited. The electromagnetic wave detector according to the present embodiment is a detector for detecting, for example, electromagnetic waves such as visible light, infrared light, near-infrared light, ultraviolet light, X rays, terahertz (THz) waves, or microwaves. In the embodiments in the present invention, these lights and radio waves are collectively referred to as electromagnetic waves. Any wavelength in the wavelength band to be detected by the electromagnetic wave detector according to the present embodiment is referred to as detection wavelength.

In the present embodiment, the term p-type graphene or n-type graphene is used as graphene which is an example of the two-dimensional material layer, where those having more holes than graphene in an intrinsic state are referred to as p-type and those having more electrons are referred to as n-type.

In the present embodiment, the term n-type or p-type is used for the material of a member in contact with graphene as an example of the two-dimensional material layer, where these terms mean that, for example, n-type refers to an electron-donating material and p-type refers to an electron-withdrawing material. Those in which there is uneven distribution of charges in the whole molecule and electrons are dominant may be referred to as n-type, and those in which holes are dominant may be referred to as p-type. One of an organic substance and an inorganic substance or a mixture thereof can be used as the materials of those contact layers.

In the present embodiment, the material forming a two-dimensional material layer may be any material in which electrons can be arranged in a single layer in a two-dimensional plane and, for example, may include at least one selected from the group consisting of graphene, transition metal dichalcogenide (TMD), black phosphorus, silicene (a two-dimensional honeycomb structure of silicon atoms), and germanene (a two-dimensional honeycomb structure of germanium atoms). Examples of the transition metal dichalcogenide include molybdenum disulfide (MoS₂), tungsten disulfide (WS₂), and tungsten diselenide (WSe₂). A two-dimensional material layer formed of at least any one of the above materials basically achieves an effect similar to that of the two-dimensional material layer formed of graphene described later.

In operation of the electromagnetic wave detector according to the present embodiment, a layer in which tunnel current is not generated is referred to as insulating layer, and a layer in which tunnel current can be generated is referred to as tunnel layer.

### First Embodiment

<Configuration of Electromagnetic Wave Detector 100>

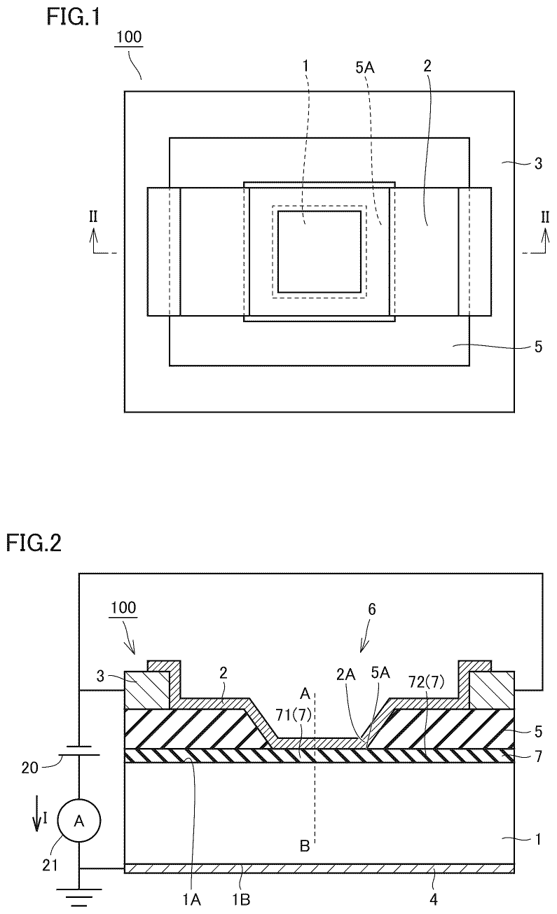

As shown in FIG. 1 and FIG. 2, an electromagnetic wave detector 100 according to a first embodiment mainly includes a semiconductor layer 1, a two-dimensional material layer 2, a first electrode part 3, a second electrode part 4, an insulating layer 5, and a unipolar barrier layer 7.

Semiconductor layer 1 has a first surface 1A and a second surface 1B. Second surface 1B is positioned on the side opposite to first surface 1A. First surface 1A and second surface 1B are, for example, flat surfaces. Two-dimensional material layer 2, first electrode part 3, insulating layer 5, and unipolar barrier layer 7 are disposed on first surface 1A of semiconductor layer 1. Second electrode part 4 is disposed on second surface 1B of semiconductor layer 1. Hereinafter, a direction orthogonal to first surface 1A and second surface 1B is defined as a vertical direction, and in the vertical direction, a direction from second surface 1B to first surface 1A is defined as upper side, and the opposite side thereof is defined as lower side. Electromagnetic wave detector 100 detects, for example, an electromagnetic wave incident on semiconductor layer 1 from the upper side.

Semiconductor layer 1 has sensitivity to a predetermined detection wavelength among the electromagnetic waves described above. Semiconductor layer 1 has an n-type or p-type conductivity type and is provided such that photocarriers are produced in semiconductor layer 1 when an electromagnetic wave with a predetermined detection wavelength is incident on semiconductor layer 1. The semiconductor material forming semiconductor layer 1 can be selected as desired according to a detection wavelength to which it should have sensitivity.

The semiconductor material forming semiconductor layer 1 contains, for example, at least one selected from the group consisting of silicon (Si), germanium (Ge), a compound semiconductor such as III-V group or II-V group semiconductor, mercury cadmium telluride (HgCdTe), indium antimonide (InSb), lead selenide (PbSe), lead sulfide (PbS), cadmium sulfide (CdS), gallium nitride (GaN), silicon carbide (SiC), gallium phosphide (GaP), indium gallium arsenide (InGaAs), and indium arsenide (InAs). Semiconductor layer 1 may be a substrate containing quantum wells or quantum dots, made of two or more semiconductor materials selected from the above group, may be a substrate containing Type II superlattice, or may be a substrate of a combination thereof.

Unipolar barrier layer 7 is disposed on first surface 1A of semiconductor layer 1. Unipolar barrier layer 7 is in contact with first surface 1A and electrically connected to semiconductor layer 1. Unipolar barrier layer 7 is disposed, for example, to cover the entire first surface 1A. Unipolar barrier layer 7 has a portion 71 exposed from insulating layer 5 described later and a portion 72 covered with insulating layer 5.

Unipolar barrier layer 7 has a physical property that does not impede carriers (for example, holes when the conductivity type of semiconductor layer 1 is n-type) that are minority carriers in semiconductor layer 1 among photocarriers (electron-hole pairs) produced in semiconductor layer 1 when an electromagnetic wave with a detection wavelength is incident on semiconductor layer 1, from flowing from semiconductor layer 1 into two-dimensional material layer 2, but impedes carriers (for example, electrons when the conductivity type of semiconductor layer 1 is n-type) that are produced by thermal excitation in two-dimensional material layer 2 and are majority carriers in semiconductor layer 1 from flowing from two-dimensional material layer 2 into semiconductor layer 1.

The material forming unipolar barrier layer 7 and the thickness of unipolar barrier layer 7 are selected such that unipolar barrier layer 7 has the above physical property.

When the conductivity type of semiconductor layer 1 in contact with unipolar barrier layer 7 is n-type, the material forming unipolar barrier layer 7 is a material having a smaller electron affinity and ionization potential and a larger band gap than the material forming semiconductor layer 1. The material forming unipolar barrier layer 7 contains, for example, at least one of nickel oxide (NiO) and manganese oxide (MnO).

When the conductivity type of semiconductor layer 1 in contact with unipolar barrier layer 7 is p-type, the material forming unipolar barrier layer 7 is a material having a larger electron affinity and ionization potential and a larger band gap than the material forming semiconductor layer 1. The material forming unipolar barrier layer 7 contains, for example, at least one of tin oxide (SnO₂), zinc oxide (ZnO), and titanium oxide (TiO₂).

It is preferable that unipolar barrier layer 7 is thinner than insulating layer 5. The thickness of unipolar barrier layer 7 is, for example, 1 nm or more and 100 nm or less.

Insulating layer 5 is disposed on unipolar barrier layer 7. Insulating layer 5

has an opening 6 to expose portion 71 of unipolar barrier layer 7. The shape of opening 6 in a planar view may be any shape and, for example, rectangular or circular. For example, only portion 71 of unipolar barrier layer 7 is exposed in the interior of opening 6. Semiconductor layer 1 is not exposed from opening 6 of insulating layer 5. Insulating layer 5 covers portion 72 of unipolar barrier layer 7.

Insulating layer 5 has a peripheral part 5A facing opening 6. Peripheral part 5A is, for example, the lower end of the side surface of insulating layer 5 facing opening 6. Unipolar barrier layer 7 includes a connection part 2A in contact with peripheral part 5A of insulating layer 5. In other words, unipolar barrier layer 7 is disposed to separate semiconductor layer 1 and peripheral part 5A of insulating layer 5 from each other. The side surface of insulating layer 5 is inclined at an acute angle relative to the lower surface of insulating layer 5 in contact with unipolar barrier layer 7.

The material forming insulating layer 5 and the thickness of insulating layer 5 are selected so as to prevent generation of tunnel current between semiconductor layer 1 and first electrode part 3.

The material forming insulating layer 5 contains, for example, at least one selected from the group consisting of silicon oxide (SiO₂), silicon nitride (Si₃N₄), hafnium oxide (HfO₂), aluminum oxide (Al₂O₃), nickel oxide (NiO), and boron nitride (BN).

First electrode part 3 is disposed at a distance from opening 6 on insulating layer 5. First electrode part 3 is electrically connected to two-dimensional material layer 2. Second electrode part 4 is in contact with semiconductor layer 1. Second electrode part 4 is in contact with, for example, second surface 1B of semiconductor layer 1. Preferably, second electrode part 4 is in ohmic contact with semiconductor layer 1.

As shown in FIG. 2, first electrode part 3 and second electrode part 4 are electrically connected to a power supply circuit. The power supply circuit includes a power supply 20 to apply a voltage between first electrode part 3 and second electrode part 4, and an ammeter 21 to measure current flowing between first electrode part 3 and second electrode part 4.

The material forming first electrode part 3 may be any conductor and preferably a material in ohmic contact with two-dimensional material layer 2. The material forming second electrode part 4 may be any conductor and preferably a material in ohmic contact with semiconductor layer 1. The materials forming first electrode part 3 and second electrode part 4 contain, for example, at least one selected from the group consisting of gold (Au), silver (Ag), copper (Cu), aluminum (Al), nickel (Ni), chromium (Cr), and palladium (Pd). A not-shown adhesion layer for enhancing the adhesion between first electrode part 3 and insulating layer 5 may be formed between first electrode part 3 and insulating layer 5. A not-shown adhesion layer for enhancing the adhesion between second electrode part 4 and semiconductor layer 1 may be formed between second electrode part 4 and semiconductor layer 1. The material forming the adhesion layer contains, for example, a metal material such as chromium (Cr) or titanium (Ti).

Two-dimensional material layer 2 extends from on opening 6 to on insulating layer 5. Two-dimensional material layer 2 is in contact with portion 71 of unipolar barrier layer 7 in opening 6. Two-dimensional material layer 2 is in contact with first electrode part 3 on insulating layer 5. Two-dimensional material layer 2 is electrically connected to each of unipolar barrier layer 7 and first electrode part 3. Preferably, two-dimensional material layer 2 is in ohmic contact with unipolar barrier layer 7. Two-dimensional material layer 2 is not in contact with semiconductor layer 1. Two-dimensional material layer 2 is electrically connected to semiconductor layer 1 through unipolar barrier layer 7.

Two-dimensional material layer 2 has, for example, a region electrically connected to semiconductor layer 1 only through unipolar barrier layer 7, and a region electrically connected to semiconductor layer 1 through unipolar barrier layer 7 and insulating layer 5. The former region is formed inside of opening 6 with respect to peripheral part 5A of insulating layer 5. The latter region is formed on a part of the above side surface of insulating layer 5. The latter region of two-dimensional material layer 2 is electrically connected to unipolar barrier layer 7 by tunnel current flowing between the lower surface and the side surface of insulating layer 5.

Two-dimensional material layer 2 is, for example, monolayer graphene or multilayer graphene. Two-dimensional material layer 2 may include, for example, graphene nanoribbons. Two-dimensional material layer 2 may include turbostatic stacked graphene formed of a plurality of monolayer graphene. As described above, the material forming two-dimensional material layer 2 may contain at least one selected from the group consisting of graphene, transition metal dichalcogenide, black phosphorus, silicene, and germanene. Further, two-dimensional material layer 2 may have a hetero stacked structure of a combination of two or more materials selected from the above group.

Two-dimensional material layer 2 has, for example, a p-type or n-type conductivity type. When the conductivity type of semiconductor layer 1 is n-type, the conductivity type of two-dimensional material layer 2 is, for example, p-type. When the conductivity type of semiconductor layer 1 is p-type, the conductivity type of two-dimensional material layer 2 is, for example, n-type. When the conductivity type of semiconductor layer 1 is n-type, the conductivity type of two-dimensional material layer 2 may be n-type. When the conductivity type of semiconductor layer 1 is p-type, the conductivity type of two-dimensional material layer 2 may be p-type.

A not-shown protective film may be formed on two-dimensional material layer 2. The material forming such a protective film contains, for example, at least one selected from the group consisting of SiO₂, Si₃N₄, HfO₂, Al₂O₃, NiO, and BN.

Electromagnetic wave detector 100 includes a first region in which second electrode part 4, semiconductor layer 1, unipolar barrier layer 7, and two-dimensional material layer 2 are stacked in sequence, a second region in which second electrode part 4, semiconductor layer 1, unipolar barrier layer 7, insulating layer 5, and two-dimensional material layer 2 are stacked in sequence, and a third region in which second electrode part 4, semiconductor layer 1, unipolar barrier layer 7, insulating layer 5, first electrode part 3, and two-dimensional material layer 2 are stacked in sequence. In a planar view, the second region is disposed, for example, such that the first region is sandwiched. In a planar view, the third region is disposed, for example, such that the first region and the second region are sandwiched.

<Method of Manufacturing Electromagnetic Wave Detector 100>

FIG. 5 is a flowchart for explaining an exemplary method of manufacturing electromagnetic wave detector 100 according to the first embodiment. Referring to FIG. 5, an exemplary method of manufacturing electromagnetic wave detector 100 shown in FIG. 1 and FIG. 2 will be described. The method of manufacturing electromagnetic wave detector 100 mainly includes a step (Si) of preparing semiconductor layer 1, a step (S2) of forming unipolar barrier layer 7, a step (S3) of depositing insulating layer 5, a step (S4) of forming second electrode part 4, a step (S5) of forming first electrode part 3, a step (S6) of forming opening 6 in insulating layer 5, and a (S7) step of forming two-dimensional material layer 2.

First of all, at step (S1), semiconductor layer 1 having first surface 1A and second surface 1B is prepared. Semiconductor layer 1 is prepared, for example, as a semiconductor substrate. As described above, the material forming semiconductor layer 1 is a semiconductor material having sensitivity to a predetermined detection wavelength.

Next, step (S2) is performed. At step (S2), unipolar barrier layer 7 is formed on first surface 1A of semiconductor layer 1. The method of forming unipolar barrier layer 7 includes, for example, but not limited to, a deposition process by vapor deposition or sputtering, a photolithography process, and an etching process. Next, step (S3) is performed. At step (S3), insulating layer 5 is deposited on

unipolar barrier layer 7. At the subsequent step (S6), insulating layer 5 is partially removed to form opening 6. The method of depositing insulating layer 5 is, for example, but not limited to, plasma chemical vapor deposition (CVD) or atomic layer deposition (ALD).

In order to suppress damage and contamination of unipolar barrier layer 7 at step (S6) of partially removing insulating layer 5, a barrier film may be formed between unipolar barrier layer 7 and insulating layer 5 immediately before this step (S3). The material forming the barrier film may be any material (material with a low etching rate) that has higher resistant to etchant used at step (S6) than the material forming insulating layer 5 and, for example, silicon nitride (SiN), aluminum oxide (Al₂O₃), or graphene.

Next, step (S4) is performed. At step (S4), second electrode part 4 is formed on second surface 1B of semiconductor layer 1. The method of forming second electrode part 4 includes, for example, but not limited to, a deposition process by vapor deposition or sputtering, a photolithography process, and an etching process. When the adhesion layer for enhancing the adhesion between second electrode part 4 and semiconductor layer 1 described above is formed, the adhesion layer may be formed at a region connected to second electrode part 4 in semiconductor layer 1, before forming second electrode part 4.

Next, step (S5) is performed. At step (S5), first electrode part 3 is formed on insulating layer 5. The method of forming first electrode part 3 includes, for example, but not limited to, a deposition process by vapor deposition or sputtering, a photolithography process, and an etching process. When the adhesion layer for enhancing the adhesion between first electrode part 3 and insulating layer 5 described above is formed, the adhesion layer may be formed at a region connected to first electrode part 3 on insulating layer 5, before forming first electrode part 3.

Next, step (S6) is performed. At step (S6), insulating layer 5 is partially removed to form opening 6. The method of forming opening 6 includes, for example, but not limited to, a photolithography process and an etching process. First, a resist mask is formed on insulating layer 5 by photolithography or electron beam (EB) lithography. The resist mask is formed to cover a region in which insulating layer 5 is to be formed and expose a region in which opening 6 is to be formed. Subsequently, insulating layer 5 is etched using the resist mask as an etching mask. The method of etching can be selected as desired from any one of wet etching using fluoric acid or the like and dry etching using reactive ion etching or the like. After etching, the resist mask is removed. In this way, opening 6 is formed in insulating layer 5. Inside opening 6, portion 71 of unipolar barrier layer 7 is exposed.

Next, step (S7) is performed. At step (S7), two-dimensional material layer 2 is formed on at least a part of each of insulating layer 5 and portion 71 of unipolar barrier layer 7. The method of forming two-dimensional material layer 2 is not limited and includes a deposition process by epitaxial growth, a photolithography process, and an etching process.

Through the above steps (S1) to (S7), electromagnetic wave detector 100 shown in FIG. 1 and FIG. 2 is manufactured. Step (S6) of forming opening 6 may be performed before step (S5) of forming first electrode part 3. In other words, in the method of manufacturing electromagnetic wave detector 100, the above step (Si), the above step (S2), the above step (S3), the above step (S4), the above step (S6), the above step (S5), and the above step (S7) may be performed in this order.

In the method of manufacturing electromagnetic wave detector 100, an electron beam (EB) lithography process may be performed instead of a photolithography process.

<Operation of Electromagnetic Wave Detector 100>

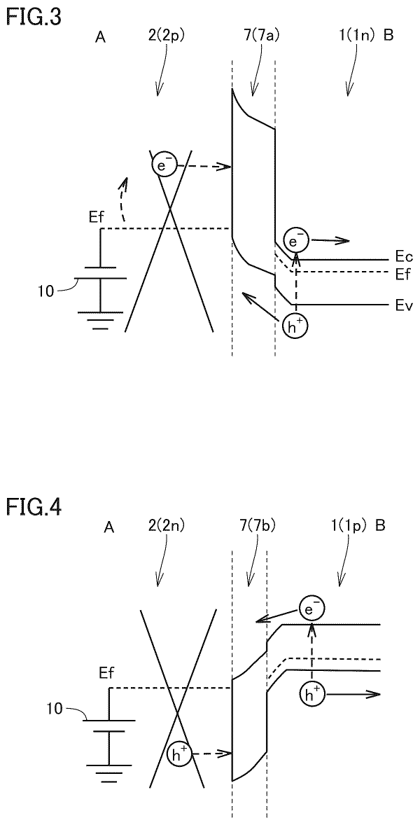

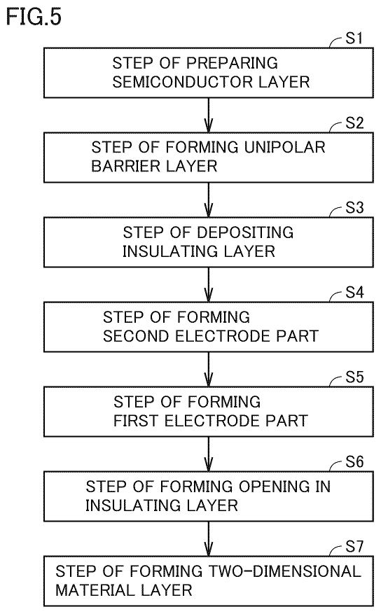

Referring now to FIG. 2 to FIG. 4, the operation of electromagnetic wave detector 100 according to the first embodiment will be described. FIG. 3 is an energy band diagram schematically showing a band structure along line A-B, where the conductivity type of semiconductor layer 1 shown in FIG. 2 is n-type and the conductivity type of two-dimensional material layer 2 is p-type. FIG. 4 is an energy band diagram schematically showing a band structure along line A-B, where the conductivity type of semiconductor layer 1 shown in FIG. 2 is p-type and the conductivity type of two-dimensional material layer 2 is n-type.

A power supply circuit (not shown) is electrically connected between first electrode part 3 and second electrode part 4. The power supply circuit includes power supply 20 to apply a voltage V between first electrode part 3 and second electrode part 4, and ammeter 21 to measure current I flowing through the power supply circuit.

The polarity of voltage V is selected according to the conductivity type (doping type) of semiconductor layer 1 such that reverse bias is applied to the junction of unipolar barrier layer 7 and semiconductor layer 1. A voltage applied between first electrode part 3 and second electrode part 4 by power supply 20 so that the potential of first electrode part 3 is higher than the potential of second electrode part 4 is defined as a positive voltage. A voltage applied between first electrode part 3 and second electrode part 4 by power supply 20 so that the potential of first electrode part 3 is lower than the potential of second electrode part 4 is defined as a negative voltage.

If the conductivity type of semiconductor layer 1 is n-type, as shown in FIG. 2 and FIG. 3, a negative voltage is applied between first electrode part 3 and second electrode part 4. Thus, electromagnetic wave detector 100 is ready to detect an electromagnetic wave with a detection wavelength. In this case, unipolar barrier layer 7 serves as an electron barrier layer 7a that does not impede a flow of holes between n-type semiconductor layer 1 (1n) and p-type two-dimensional material layer 2 (2p) but impedes a flow of electrons between semiconductor layer In and two-dimensional material layer 2p.

Specifically, as shown in FIG. 3, in a state (dark state) of not being irradiated with an electromagnetic wave with a detection wavelength, unipolar barrier layer 7 impedes an electron thermally excited in two-dimensional material layer 2 from flowing into semiconductor layer 1 by thermionic emission. As shown in FIG. 3, in a state of being irradiated with an electromagnetic wave with a detection wavelength, unipolar barrier layer 7 does not impede the hole of an electron-hole pair (photocarrier) generated in semiconductor layer In from flowing into two-dimensional material layer 2p. In a state of being irradiated with an electromagnetic wave with a detection wavelength, the hole of an electron-hole pair generated in semiconductor layer In is attracted toward two-dimensional material layer 2p. Energy Ev at the top of the valence band of unipolar barrier layer 7 is higher than energy Ev at the top of the valence band of semiconductor layer 1n. Therefore, the hole produced in semiconductor layer In is not impeded by unipolar barrier layer 7 but injected into two-dimensional material layer 2p and extracted as photocurrent. Photocurrent is detected as change of current I.

If the conductivity type of semiconductor layer 1 is p-type, as shown in FIG. 4, a positive voltage is applied between first electrode part 3 and second electrode part 4. Thus, electromagnetic wave detector 100 is ready to detect an electromagnetic wave with a detection wavelength. In this case, unipolar barrier layer 7 serves as a hole barrier layer 7b that does not impede a flow of electrons between p-type semiconductor layer 1 (1p) and n-type two-dimensional material layer 2 (2n) but impedes a flow of holes between semiconductor layer 1p and two-dimensional material layer 2n. Specifically, as shown in FIG. 4, in the dark state, unipolar barrier layer 7

impedes a hole produced by thermal excitation of an electron in two-dimensional material layer 2n from flowing into semiconductor layer 1p. In a state of being irradiated with an electromagnetic wave with a detection wavelength, unipolar barrier layer 7 does not impede the electron of an electron-hole pair (photocarrier) generated in semiconductor layer 1p from flowing into two-dimensional material layer 2n. In a state of being irradiated with an electromagnetic wave with a detection wavelength, the electron of an electron-hole pair generated in semiconductor layer 1p is attracted toward two-dimensional material layer 2n. Energy Ec at the bottom of the conduction band of unipolar barrier layer 7 is lower than energy Ec at the bottom of the conduction band of semiconductor layer 1p. Therefore, the electron produced in semiconductor layer 1p is not impeded by unipolar barrier layer 7 but injected into two-dimensional material layer 2n and extracted as photocurrent. Photocurrent is detected as change of current I.

<Effect of Electromagnetic Wave Detector 100>

In electromagnetic wave detector 100, two-dimensional material layer 2 is electrically connected to semiconductor layer 1 through unipolar barrier layer 7. Thus, as described above, irrespective of the conductivity type of semiconductor layer 1, unipolar barrier layer 7 does not impede a photocarrier from flowing from semiconductor layer 1 into two-dimensional material layer 2 in a state of being irradiated with an electromagnetic wave with a detection wavelength, but suppresses flowing of an electron or hole from two-dimensional material layer 2 into semiconductor layer 1 in the dark state. As a result, in electromagnetic wave detector 100, dark current is suppressed while extraction of photocarriers is not impeded. In particular, when the same voltage is applied to each of electromagnetic wave detector 100 and the detectors described in PTL 1 and PTL 2, the amount of dark current produced in electromagnetic wave detector 100 is smaller than the amount of dark current produced in the detectors described in PTL 1 and PTL 2. As a result, in electromagnetic wave detector 100, the operating temperature can be increased, compared with the detectors described in PTL 1 and PTL 2. Further, in electromagnetic wave detector 100, a larger voltage V can be applied between first electrode part 3 and second electrode part 4, compared with the detectors described in PTL 1 and PTL 2. In this case, when an electromagnetic wave with equivalent wavelength and intensity is applied to each of electromagnetic wave detector 100 and the detectors described in PTL 1 and PTL 2, the amount of photocurrent produced in electromagnetic wave detector 100 is larger than the amount of photocurrent produced in the detectors described in PTL 1 and PTL 2.

When a voltage V is applied between first electrode part 3 and second electrode part 4 and electromagnetic wave detector 100 is ready to detect an electromagnetic wave with a detection wavelength, an electric field is concentrated on the edge of opening 6 (peripheral part 5A of insulating layer 5). This is because a portion closest to first electrode part 3 in a region in contact with unipolar barrier layer 7 (a region electrically connected to semiconductor layer 1) in two-dimensional material layer 2 is disposed at the edge of opening 6. At the edge of opening 6 where an electric field is concentrated, carriers produced by thermal excitation tend to flow into semiconductor layer 1. In electromagnetic wave detector 100, since unipolar barrier layer 7 is disposed over the entire opening 6 including the edge, the amount of dark current produced in electromagnetic wave detector 100 is smaller than the amount of dark current produced in a detector in which unipolar barrier layer 7 is disposed only inside of the edge in opening 6.

In the detectors described in PTL 1 and PTL 2, the two-dimensional material layer and the semiconductor layer are in direct contact with each other. In such a structure, a native oxide film may be formed at the interface between the two-dimensional material layer and the semiconductor layer. The thickness of the native oxide film sometimes increases with time and an external environment. Thus, the characteristics of the electromagnetic wave detector may become unstable, or the two-dimensional material layer may be electrically insulated from the semiconductor layer, leading to malfunction of the electromagnetic wave detector. By contrast, in electromagnetic wave detector 100, two-dimensional material layer 2 and semiconductor layer 1 are not in direct contact with each other, and unipolar barrier layer 7 is disposed between them. As described above, unipolar barrier layer 7 can be formed of an oxide semiconductor material with relatively high stability. For example, when formed as an electron barrier layer, unipolar barrier layer 7 can be formed of NiO with high stability. In this case, the reliability of electromagnetic wave detector 100 can be enhanced, compared with the detectors described in PTL 1 and PTL 2, because a native oxide film is less likely to be formed at the interface between two-dimensional material layer 2 and unipolar barrier layer 7 and the interface between unipolar barrier layer 7 and semiconductor layer 1.

<Modification>

A combination of the conductivity types of semiconductor layer 1 and two-dimensional material layer 2 in electromagnetic wave detector 100 is not limited to the combination shown in FIG. 3 or FIG. 4. In FIG. 3 and FIG. 4, the conductivity type of two-dimensional material layer 2 is different from the conductivity type of semiconductor layer 1, but the conductivity type of two-dimensional material layer 2 of electromagnetic wave detector 100 may be the same as the conductivity type of semiconductor layer 1.

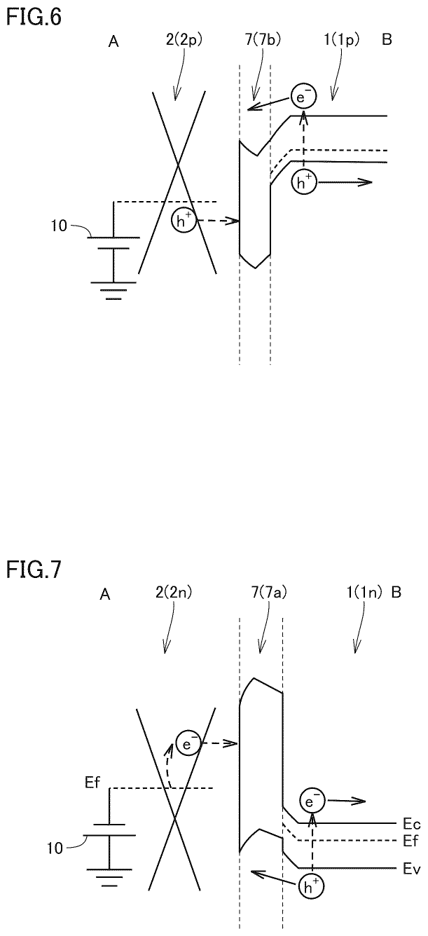

FIG. 6 is an energy band diagram schematically showing a band structure along line A-B, where the conductivity type of each of semiconductor layer 1 and two-dimensional material layer 2 shown in FIG. 2 is p-type. FIG. 7 is an energy band diagram schematically showing a band structure along line A-B, where the conductivity type of each of semiconductor layer 1 and two-dimensional material layer 2 shown in FIG. 2 is n-type.

As shown in FIG. 6, when the conductivity type of each of semiconductor layer 1 and two-dimensional material layer 2 is p-type, the band structure of semiconductor layer 1p, unipolar barrier layer 7, and two-dimensional material layer 2p is a pnp-type diode structure.

A pnp-type diode structure may be formed even in the detector described in PTL 2, but in this case, a relatively large barrier is formed at the junction interface between the p-type two-dimensional material layer and the n-type first semiconductor portion. Specifically, the energy at the bottom of the conduction band of the n-type first semiconductor portion in the vicinity of the junction interface is equally as high as the energy at the bottom of the conduction band of the p-type second semiconductor portion. Thus, the above barrier impedes extraction of electrons produced in the pn junction interface between the first semiconductor portion and the second semiconductor portion. On the other hand, if a negative voltage applied to the pn junction of the p-type two-dimensional material layer and the n-type first semiconductor portion is increased in order to enhance the electron extraction efficiency, holes produced by thermal excitation tend to flow from the p-type two-dimensional material layer into the n-type semiconductor layer, thereby increasing dark current.

By contrast, in electromagnetic wave detector 100, even though the pnp-type diode structure shown in FIG. 6 is implemented, energy Ec at the bottom of the conduction band of unipolar barrier layer 7 in the vicinity of the interface between two-dimensional material layer 2p and unipolar barrier layer 7 is sufficiently lower than energy Ec at the bottom of the conduction band of semiconductor layer 1p. Thus, unipolar barrier layer 7 does not impede electrons produced in semiconductor layer 1p from flowing into two-dimensional material layer 2p. On the other hand, unipolar barrier layer 7 impedes holes produced by thermal excitation in two-dimensional material layer 2p from flowing into semiconductor layer 1p. In other words, unipolar barrier layer 7 can act as a hole barrier layer.

As shown in FIG. 7, when the conductivity type of each of semiconductor layer 1 and two-dimensional material layer 2 is n-type, the band structure of semiconductor layer 1n, unipolar barrier layer 7, and two-dimensional material layer 2n is an npn-type diode structure.

As described above, the npn-type diode structure as shown in FIG. 21 may be formed even in the detector described in PTL 2, but in this case, a relatively large barrier is formed at the junction interface between the n-type two-dimensional material layer and the p-type first semiconductor portion. Specifically, the energy at the top of the valence band of the p-type first semiconductor portion in the vicinity of the junction interface is equally as low as the energy at the top of the valence band of the n-type second semiconductor portion. Thus, the above barrier impedes extraction of holes produced in the pn junction interface between the first semiconductor portion and the second semiconductor portion. On the other hand, if a negative voltage applied to the pn junction of the n-type two-dimensional material layer and the p-type first semiconductor portion is increased in order to enhance the hole extraction efficiency, electrons thermally excited in the n-type two-dimensional material layer tend to flow into the p-type semiconductor layer, thereby increasing dark current.

By contrast, in electromagnetic wave detector 100, even though the npn-type diode structure shown in FIG. 7 is implemented, energy Ev at the top of the valence band of unipolar barrier layer 7 in the vicinity of the interface between two-dimensional material layer 2n and unipolar barrier layer 7 is sufficiently higher than energy Ev at the top of the valence band of semiconductor layer 1n. Thus, unipolar barrier layer 7 does not impede holes produced in semiconductor layer 1n from flowing into two-dimensional material layer 2n. On the other hand, unipolar barrier layer 7 impedes electrons produced by thermal excitation in two-dimensional material layer 2n from flowing into semiconductor layer 1n. In other words, unipolar barrier layer 7 can act as an electron barrier layer.

In this way, in electromagnetic wave detector 100, since unipolar barrier layer 7 acts as an electron barrier layer or a hole barrier layer, irrespective of a combination of the conductivity types of semiconductor layer 1 and two-dimensional material layer 2, photocarriers can be efficiently extracted while dark current is suppressed.

### Second Embodiment

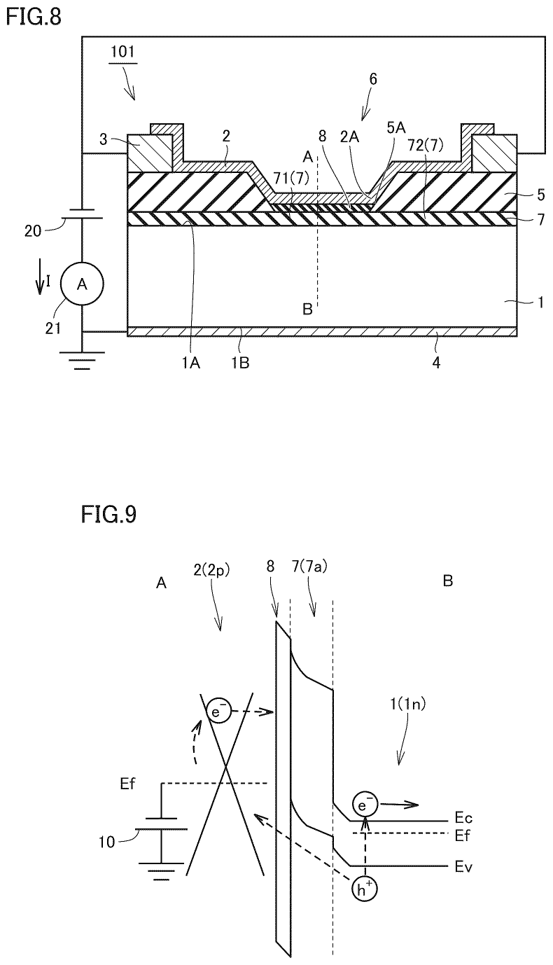

FIG. 8 is a cross-sectional view of an electromagnetic wave detector 101 according to a second embodiment. As shown in FIG. 8, electromagnetic wave detector 101 basically has a similar configuration and achieves an effect similar to that of electromagnetic wave detector 100 according to the first embodiment but differs from electromagnetic wave detector 100 in that it further includes a tunnel layer 8. In the following, the points of difference from electromagnetic wave detector 100 will mainly be described.

<Configuration of Electromagnetic Wave Detector 101>

Tunnel layer 8 is disposed in the interior of opening 6. Tunnel layer 8 is disposed between two-dimensional material layer 2 and unipolar barrier layer 7 in the vertical direction. Tunnel layer 8 is in contact with each of two-dimensional material layer 2 and unipolar barrier layer 7. Tunnel layer 8 is not in contact with semiconductor layer 1.

Tunnel layer 8 is provided such that tunnel current can be produced in operation of electromagnetic wave detector 101. The material forming tunnel layer 8 may be any material that has electrical insulating properties, and contains, for example, at least one selected from the group consisting of metal oxides such as HfO₂ and Al₂O₃, oxides or nitrides of semiconductor such as SiO₂ and Si₃N₄, and BN. The thickness of tunnel layer 8 is, for example, 1 nm or more and 10 nm or less.

In electromagnetic wave detector 101, peripheral part 5A of insulating layer 5 is, for example, a portion in contact with tunnel layer 8 in the side surface of insulating layer 5 facing opening 6. Connection part 2A of two-dimensional material layer 2 is in contact with peripheral part 5A of insulating layer 5. Tunnel layer 8 is disposed between connection part 2A of two-dimensional material layer 2 and unipolar barrier layer 7.

Two-dimensional material layer 2 is electrically connected to unipolar barrier layer 7 by tunnel current flowing through tunnel layer 8.

The method of manufacturing electromagnetic wave detector 101 differs from the method of manufacturing electromagnetic wave detector 100 in that it further includes a step of forming tunnel layer 8 after step (S6) of forming opening 6 and before step (S7) of forming two-dimensional material layer 2. In the step of forming tunnel layer 8, the method of forming tunnel layer 8 includes, for example, but not limited to, a deposition process by ALD, vacuum evaporation, or sputtering, a photolithography process, and an etching process.

<Effect of Electromagnetic Wave Detector 101>

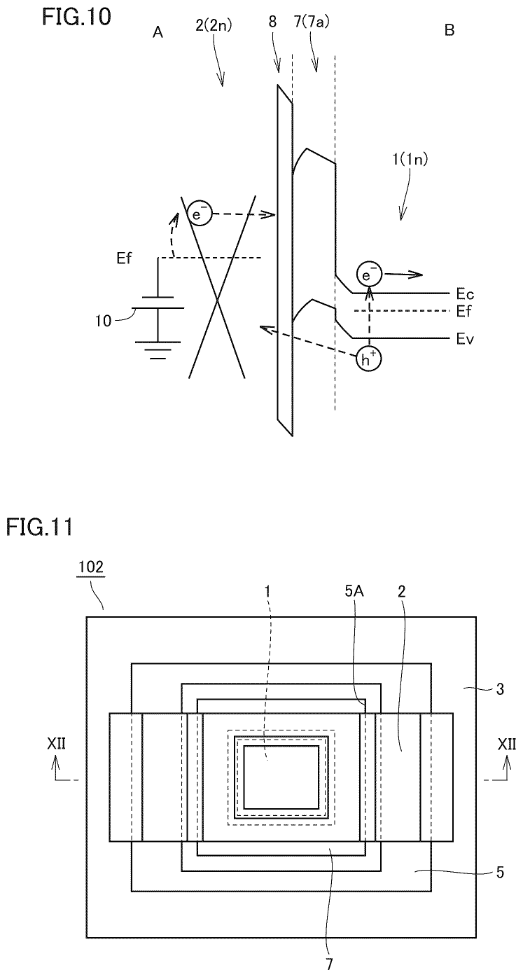

FIG. 9 is an energy band diagram schematically showing a band structure along line A-B, where the conductivity type of semiconductor layer 1 shown in FIG. 8 is n-type and the conductivity type of two-dimensional material layer 2 is p-type. FIG. 10 is an energy band diagram schematically showing a band structure along line A-B, where the conductivity type of semiconductor layer 1 shown in FIG. 8 is n-type and the conductivity type of two-dimensional material layer 2 is n-type.

In either case, even if an electron thermally excited in two-dimensional material layer 2 passes through tunnel layer 8, unipolar barrier layer 7 impedes the thermoelectron from flowing into semiconductor layer 1n. On the other hand, unipolar barrier layer 7 does not impede a hole produced in semiconductor layer 1n when an electromagnetic wave with a detection wavelength is incident on semiconductor layer 1n, from flowing from semiconductor layer 1n into tunnel layer 8.

Accordingly, the hole produced in semiconductor layer 1n passes through tunnel layer 8 and flows into two-dimensional material layer 2.

In electromagnetic wave detector 101, the conductivity type of semiconductor layer 1 may be p-type and the conductivity type of two-dimensional material layer 2 may be n-type or p-type, as in electromagnetic wave detector 100. Even if a hole produced by thermal excitation in two-dimensional material layer 2 passes through tunnel layer 8, unipolar barrier layer 7 impedes the hole from flowing into semiconductor layer 1p. On the other hand, unipolar barrier layer 7 does not impede an electron produced in semiconductor layer 1p when an electromagnetic wave with a detection wavelength is incident on semiconductor layer 1p, from flowing from semiconductor layer 1p into tunnel layer 8. Accordingly, the electron produced in semiconductor layer 1p passes through tunnel layer 8 and flows into two-dimensional material layer 2.

In other words, unipolar barrier layer 7 of electromagnetic wave detector 101 can act in the same manner as unipolar barrier layer 7 of electromagnetic wave detector 100.

Further, in electromagnetic wave detector 100 in which tunnel layer 8 is not disposed between two-dimensional material layer 2 and unipolar barrier layer 7, photocarriers flowing from semiconductor layer 1n into two-dimensional material layer 2 when an electromagnetic wave with a detection wavelength is incident on semiconductor layer 1 pass through the interface between two-dimensional material layer 2 and unipolar barrier layer 7 and therefore may scatter or recombine with electrons or holes due to defects or foreign matter present in the interface. In this case, at least one of the lifetime and the mobility of photocarriers may be reduced, and the photocarrier extraction efficiency may be reduced.

By contrast, in electromagnetic wave detector 101, since photocarriers flow as tunnel current between two-dimensional material layer 2 and unipolar barrier layer 7, photocarriers are not influenced by scattering or recombination at the interface between two-dimensional material layer 2 and unipolar barrier layer 7. Specifically, the density of defects or foreign matter present in the interface between two-dimensional material layer 2 and tunnel layer 8, the interior of tunnel layer 8, and the interface between unipolar barrier layer 7 and tunnel layer 8 can be kept lower than the density of defects or foreign matter present in the interface between two-dimensional material layer 2 and unipolar barrier layer 7. Thus, in electromagnetic wave detector 101, the lifetime and the mobility of photocarriers are less likely to be reduced and the photocarrier extraction efficiency is less likely to be reduced, compared with electromagnetic wave detector 100. As a result, the amount of photocurrent produced in electromagnetic wave detector 101 is larger than the amount of photocurrent produced in electromagnetic wave detector 100.

More specifically, the film quality of unipolar barrier layer 7 is typically not as high as the film quality of tunnel layer 8 (insulating film). Thus, when two-dimensional material layer 2 and unipolar barrier layer 7 are in direct contact with each other, relatively many defect levels (interface levels) are formed at the interface between them. In this case, the amount of electrons (dark current) injected from two-dimensional material layer 2 to unipolar barrier layer 7 through the defect levels is relatively large. If the electrons recombine with photocarriers (holes), the light extraction efficiency is reduced. On the other hand, the number of defect levels formed in the interface between two-dimensional material layer 2 and tunnel layer 8 can be made smaller than the number of defect levels formed in the interface between two-dimensional material layer 2 and unipolar barrier layer 7. Thus, in electromagnetic wave detector 101 in which two-dimensional material layer 2 and tunnel layer 8 are in direct contact with each other, dark current is reduced, and reduction of the photocarrier extraction efficiency is suppressed, compared with electromagnetic wave detector 100 in which two-dimensional material layer 2 and unipolar barrier layer 7 are in direct contact with each other.

### Third Embodiment

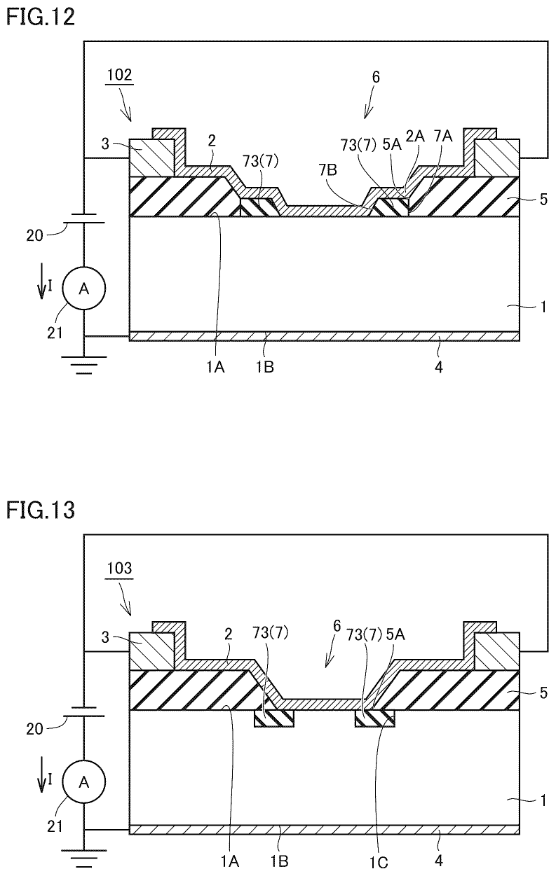

FIG. 11 is a plan view of an electromagnetic wave detector 102 according to a third embodiment. FIG. 12 is a cross-sectional view of electromagnetic wave detector 102 according to the third embodiment. As shown in FIG. 11 and FIG. 12, electromagnetic wave detector 102 basically has a similar configuration and achieves an effect similar to that of electromagnetic wave detector 100 according to the first embodiment, but differs from electromagnetic wave detector 100 in that unipolar barrier layer 7 has an annular portion 73 disposed annularly in the interior of opening 6 in a planar view and that two-dimensional material layer 2 is in contact with a part of the semiconductor layer positioned inside of annular portion 73 in a planar view. In a different point of view, electromagnetic wave detector 102 differs from electromagnetic wave detector 100 in that unipolar barrier layer 7 is disposed only at the edge of opening 6. In the following, the points of difference from electromagnetic wave detector 100 will mainly be described.

<Configuration of Electromagnetic Wave Detector 102>

In electromagnetic wave detector 102, peripheral part 5A of insulating layer 5 is, for example, the upper end of the side surface of insulating layer 5 facing opening 6. Connection part 2A of two-dimensional material layer 2 is in contact with peripheral part 5A of insulating layer 5. The side surface of insulating layer 5 is, for example, orthogonal to first surface 1A.

Annular portion 73 of unipolar barrier layer 7 is disposed on first surface 1A. Annular portion 73 is disposed along peripheral part 5A of insulating layer 5. Annular portion 73 is in contact with each of semiconductor layer 1 and two-dimensional material layer 2.

An outer peripheral surface 7A of annular portion 73 is in contact with the side surface of insulating layer 5. The upper end of outer peripheral surface 7A of annular portion 73 is in contact with each of peripheral part 5A of insulating layer 5 and two-dimensional material layer 2. The lower end of outer peripheral surface 7A of annular portion 73 is in contact with each of the lower end of the side surface of insulating layer 5 and semiconductor layer 1. An inner peripheral surface 7B of annular portion 73 is in contact with two-dimensional material layer 2. The lower surface including the respective lower ends of outer peripheral surface 7A and inner peripheral surface 7B of annular portion 73 is in contact with semiconductor layer 1. The upper surface including the respective upper ends of outer peripheral surface 7A and inner peripheral surface 7B of annular portion 73 is in contact with two-dimensional material layer 2.

Outer peripheral surface 7A of annular portion 73 is formed, for example, with a surface orthogonal to first surface 1A. Inner peripheral surface 7B is formed, for example, with an inclined surface inclined at an acute angle relative to the lower surface of annular portion 73.

In two-dimensional material layer 2, a portion disposed inside of inner peripheral surface 7B of annular portion 73 is in contact with semiconductor layer 1. The method of manufacturing electromagnetic wave detector 102 differs from the method of manufacturing electromagnetic wave detector 100 in that unipolar barrier layer 7 is formed to have annular portion 73 at step (S2) of forming unipolar barrier layer 7.

<Effect of Electromagnetic Wave Detector 102>

When electromagnetic wave detector 102 is ready to detect an electromagnetic wave with a detection wavelength, an electric field is concentrated on the edge of opening 6 (peripheral part 5A of insulating layer 5), in the same manner as in electromagnetic wave detector 100 described above. Also in electromagnetic wave detector 102, since unipolar barrier layer 7 is disposed between two-dimensional material layer 2 and semiconductor layer 1 at the edge of opening 6, the amount of dark current produced in electromagnetic wave detector 102 is smaller than in a detector in which unipolar barrier layer 7 is disposed only inside of the edge in opening 6, in the same manner as in electromagnetic wave detector 100.

Further, when the conductivity type of semiconductor layer 1 is n-type, holes (photocarriers) generated immediately below insulating layer 5 with irradiation of an electromagnetic wave with a detection wavelength flow into the edge of opening 6 where an electric field is concentrated. Since unipolar barrier layer 7 suppresses dark current flowing through the edge of opening 6, holes flowing through the edge of opening 6 are less likely to recombine with electrons. Thus, the photocarrier extraction efficiency of electromagnetic wave detector 102 is enhanced, compared with the photocarrier extraction efficiency of a detector in which unipolar barrier layer 7 is disposed only inside of the edge in opening 6.

Further, in electromagnetic wave detector 102, unipolar barrier layer 7 is disposed only at the edge of opening 6, and in a portion other than the edge of opening 6, two-dimensional material layer 2 is in direct contact with semiconductor layer 1 without unipolar barrier layer 7 interposed. Thus, in electromagnetic wave detector 102, it is unlikely that unipolar barrier layer 7 serves as a resistance component connected in series with the power supply circuit to reduce the amount of photocurrent.

### Fourth Embodiment

FIG. 13 is a cross-sectional view of an electromagnetic wave detector 103 according to a fourth embodiment. As shown in FIG. 13, electromagnetic wave detector 103 basically has a similar configuration and achieves an effect similar to that of electromagnetic wave detector 102 according to the third embodiment but differs from electromagnetic wave detector 102 in that unipolar barrier layer 7 is buried in semiconductor layer 1. In the following, the points of difference from electromagnetic wave detector 102 will mainly be described.

<Configuration of Electromagnetic Wave Detector 103>

Semiconductor layer 1 has a recess 1C depressed relative to first surface 1A. Recess 1C is formed annularly to overlap peripheral part 5A of insulating layer 5 in a planar view.

Annular portion 73 of unipolar barrier layer 7 is disposed in the interior of recess 1C. Annular portion 73 is disposed annularly to overlap peripheral part 5A of insulating layer 5 in a planar view. The upper surface of annular portion 73 is in contact with peripheral part 5A of insulating layer 5. The upper surface of annular portion 73 is formed to be flush with first surface 1A of semiconductor layer 1.

In electromagnetic wave detector 103, peripheral part 5A of insulating layer 5 is, for example, the lower end of the side surface of insulating layer 5 facing opening 6. Connection part 2A of two-dimensional material layer 2 is in contact with peripheral part 5A of insulating layer 5.

In two-dimensional material layer 2, a portion in contact with annular portion 73 of unipolar barrier layer 7 and a portion in contact with semiconductor layer 1 are aligned in a direction along first surface 1A. In other words, two-dimensional material layer 2 does not have a step portion between the portion in contact with annular portion 73 of unipolar barrier layer 7 and the portion in contact with semiconductor layer 1.

The method of manufacturing electromagnetic wave detector 103 differs from the method of manufacturing electromagnetic wave detector 100 in that semiconductor layer 1 having recess 1C is prepared at step (S1) of preparing semiconductor layer 1 and that unipolar barrier layer 7 is formed inside recess 1C at step (S2) of forming unipolar barrier layer 7. At step (S1), the method of forming recess 1C includes, for example, but not limited to, a photolithography process and an etching process. At step (S2), for example, unipolar barrier layer 7 is deposited such that the thickness of unipolar barrier layer 7 is equal to the depth of recess 1C. At step (S2), after unipolar barrier layer 7 is deposited such that the thickness of unipolar barrier layer 7 is larger than the depth of recess 1C, unipolar barrier layer 7 formed on first surface 1A may be removed, for example, by chemical mechanical polishing (CMP) or the like.

<Effect of Electromagnetic Wave Detector 103>

In electromagnetic wave detector 102, the portion in contact with annular portion 73 of unipolar barrier layer 7 and the portion in contact with semiconductor layer 1 in two-dimensional material layer 2 are disposed in the form of a step. In other words, two-dimensional material layer 2 of electromagnetic wave detector 102 has a step portion between the portion in contact with annular portion 73 of unipolar barrier layer 7 and the portion in contact with semiconductor layer 1. Thus, in electromagnetic wave detector 102, the step portion may cause reduction of mobility of photocarriers in two-dimensional material layer 2. By contrast, two-dimensional material layer 2 of electromagnetic wave detector 103 does not have a step portion between the portion in contact with annular portion 73 of unipolar barrier layer 7 and the portion in contact with semiconductor layer 1. Thus, in electromagnetic wave detector 103, reduction of the mobility of photocarriers due to the step portion does not occur.

### Fifth Embodiment

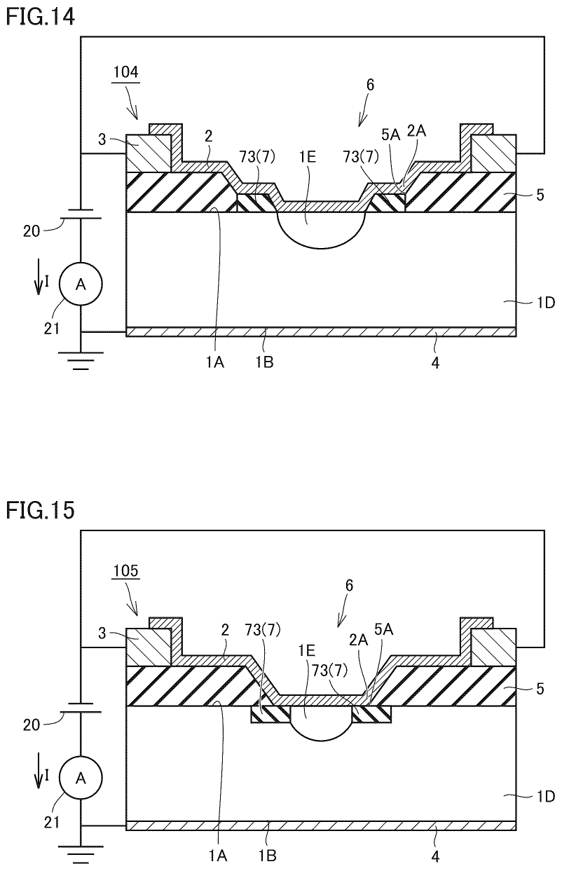

FIG. 14 is a cross-sectional view of an electromagnetic wave detector 104 according to a fifth embodiment. As shown in FIG. 14, electromagnetic wave detector 104 basically has a similar configuration and achieves an effect similar to that of electromagnetic wave detector 102 according to the third embodiment but differs from electromagnetic wave detector 102 in that semiconductor layer 1 includes a first semiconductor region 1D having a first conductivity type and a second semiconductor region 1E having a second conductivity type. In the following, the points of difference from electromagnetic wave detector 102 will mainly be described.

<Configuration of Electromagnetic Wave Detector 104>

When the conductivity type of first semiconductor region 1D is n-type, the conductivity type of second semiconductor region 1E is p-type. When the conductivity type of first semiconductor region 1D is p-type, the conductivity type of second semiconductor region 1E is n-type. First semiconductor region 1D and second semiconductor region 1E form a pn junction. The pn junction interface between first semiconductor region 1D and second semiconductor region 1E is formed immediately below two-dimensional material layer 2. The pn junction interface between first semiconductor region 1D and second semiconductor region 1E is, for example, in contact with two-dimensional material layer 2.

Each of first semiconductor region 1D and second semiconductor region 1E is revealed on first surface 1A. First semiconductor region 1D is in contact with each of second electrode part 4, insulating layer 5, and unipolar barrier layer 7. Second semiconductor region 1E is in contact with two-dimensional material layer 2. Second semiconductor region 1E is, for example, not in contact with unipolar barrier layer 7.

In a planar view, second semiconductor region 1E is formed inside of opening 6 with respect to peripheral part 5A of insulating layer 5. In a planar view, second semiconductor region 1E is formed inside of inner peripheral surface 7B of annular portion 73 of unipolar barrier layer 7.

Preferably, the impurity concentration of each of first semiconductor region 1D and second semiconductor region 1E is set such that the depletion layer width of the pn junction is relatively large.

The method of manufacturing electromagnetic wave detector 103 differs from the method of manufacturing electromagnetic wave detector 100 in that, for example, semiconductor layer 1 having first semiconductor region 1D and second semiconductor region 1E is prepared at step (Si) of preparing semiconductor layer 1. In the method of manufacturing electromagnetic wave detector 103, first semiconductor region 1D and second semiconductor region 1E may be formed after unipolar barrier layer 7 and insulating layer 5 are formed. The method of forming first semiconductor region 1D and second semiconductor region 1E includes, for example, but not limited to, a step of forming a mask for impurity injection having an opening in a region where second semiconductor region 1E is to be formed, an impurity injection step using the mask, and a step of removing the mask. The method of forming the mask for impurity injection includes, for example, but not limited to, a deposition process of a mask material, a photolithography process, and an etching process.

Also in electromagnetic wave detector 103, the polarity of voltage V is selected according to the conductivity type of first semiconductor region 1D in contact with unipolar barrier layer 7 such that reverse bias is applied to the junction of unipolar barrier layer 7 and semiconductor layer 1.

If the conductivity type of first semiconductor region 1D is n-type, as shown in FIG. 14, a negative voltage is applied between first electrode part 3 and second electrode part 4. If the conductivity type of first semiconductor region 1D is p-type, a positive voltage is applied between first electrode part 3 and second electrode part 4.

<Effect of Electromagnetic Wave Detector 104>

In electromagnetic wave detector 104, since the pn junction of first semiconductor region 1D and second semiconductor region 1E is formed between two-dimensional material layer 2 and first semiconductor region 1D, dark current is suppressed, compared with electromagnetic wave detector 102.

Further, in electromagnetic wave detector 104, since a built-in potential difference at the pn junction of first semiconductor region 1D and second semiconductor region 1E is produced, photocarriers can be extracted more efficiently, compared with electromagnetic wave detector 102 in which the built-in potential difference is not produced.

<Modification>

FIG. 15 is a cross-sectional view of an electromagnetic wave detector 105 that is a modification of electromagnetic wave detector 104. As shown in FIG. 15, electromagnetic wave detector 105 has a configuration similar to electromagnetic wave detector 103 according to the fourth embodiment, except that semiconductor layer 1 includes first semiconductor region 1D having the first conductivity type and second semiconductor region 1E having the second conductivity type. In such electromagnetic wave detector 105, an effect similar to that of electromagnetic wave detector 103 and electromagnetic wave detector 104 is achieved.

### Sixth Embodiment

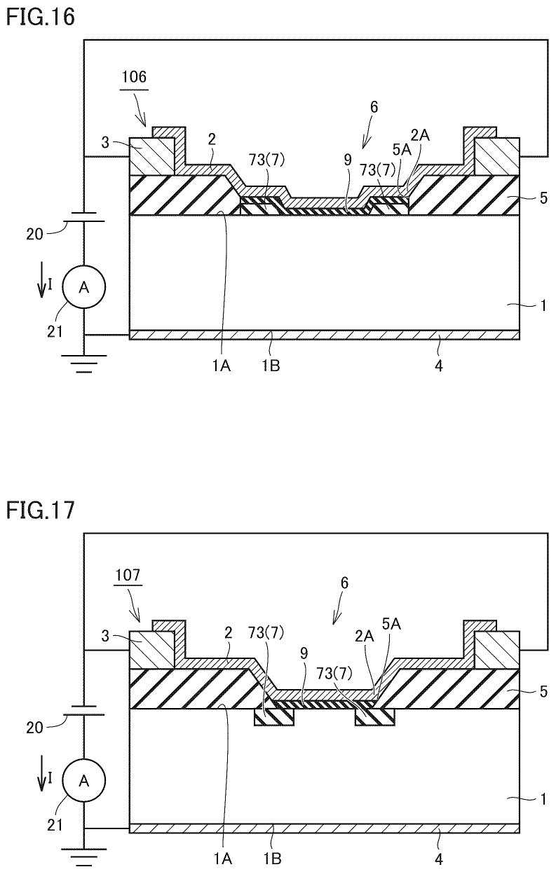

FIG. 16 is a cross-sectional view of an electromagnetic wave detector 106 according to a sixth embodiment. As shown in FIG. 16, electromagnetic wave detector 106 basically has a similar configuration and achieves an effect similar to that of electromagnetic wave detector 102 according to the third embodiment but differs from electromagnetic wave detector 102 in that it further includes a tunnel layer 9. In the following, the points of difference from electromagnetic wave detector 102 will mainly be described.

<Configuration of Electromagnetic Wave Detector 106>

Tunnel layer 9 has a first portion 9A disposed between semiconductor layer 1 and two-dimensional material layer 2 in the vertical direction, and a second portion 9B disposed between unipolar barrier layer 7 and two-dimensional material layer 2 in the vertical direction. First portion 9A is in contact with each of semiconductor layer 1 and two-dimensional material layer 2. Second portion 9B is in contact with each of two-dimensional material layer 2 and unipolar barrier layer 7.

Tunnel layer 9 is provided such that tunnel current can be produced in operation of electromagnetic wave detector 106. The material forming tunnel layer 9 may be any material that has electrical insulating properties, for example, may be any material that has electrical insulating properties, and contains, for example, at least one selected from the group consisting of metal oxides such as HfO₂ and Al₂O₃, oxides or nitrides of semiconductor such as SiO₂ and Si₃N₄, and BN. The thickness of tunnel layer 9 is, for example, 1 nm or more and 10 nm or less.

Two-dimensional material layer 2 is electrically connected to each of semiconductor layer 1 and unipolar barrier layer 7 by tunnel current flowing through tunnel layer 9.

The method of manufacturing electromagnetic wave detector 106 differs from the method of manufacturing electromagnetic wave detector 102 in that it further includes a step of forming tunnel layer 9 after step (S6) of forming opening 6 and before step (S7) of forming two-dimensional material layer 2. In the step of forming tunnel layer 9, the method of forming tunnel layer 9 includes, for example, but not limited to, a deposition process by ALD, vacuum evaporation, or sputtering, a photolithography process, and an etching process.

<Effect of Electromagnetic Wave Detector 106>

In electromagnetic wave detector 102 in which tunnel layer 8 is not disposed between two-dimensional material layer 2 and semiconductor layer 1, photocarriers flowing from semiconductor layer 1 into two-dimensional material layer 2 when an electromagnetic wave with a detection wavelength is incident on semiconductor layer 1 may scatter or recombine with electrons or holes due to defects or foreign matter present in the interface between two-dimensional material layer 2 and semiconductor layer 1. In this case, at least one of the lifetime and the mobility of photocarriers may be reduced, and the photocarrier extraction efficiency may be reduced.

By contrast, in electromagnetic wave detector 106, since photocarriers flow as tunnel current between two-dimensional material layer 2 and semiconductor layer 1 or between two-dimensional material layer 2 and unipolar barrier layer 7, photocarriers are not influenced by scattering or recombination at the interface between two-dimensional material layer 2 and semiconductor layer 1 and the interface between two-dimensional material layer 2 and unipolar barrier layer 7. Thus, in electromagnetic wave detector 106, the lifetime and the mobility of photocarriers are less likely to be reduced and the photocarrier extraction efficiency is less likely to be reduced, compared with electromagnetic wave detector 102. As a result, the amount of photocurrent produced in electromagnetic wave detector 106 is larger than the amount of photocurrent produced in electromagnetic wave detector 102.

<Modification>

FIG. 17 is a cross-sectional view of an electromagnetic wave detector 107 that is a modification of electromagnetic wave detector 106. As shown in FIG. 17, electromagnetic wave detector 107 has a configuration similar to electromagnetic wave detector 103 according to the fourth embodiment, except that it includes tunnel layer 9.

In such electromagnetic wave detector 107, an effect similar to that of electromagnetic wave detector 103 and electromagnetic wave detector 106 is achieved.

The electromagnetic wave detector according to the sixth embodiment may have a configuration similar to electromagnetic wave detector 104, 105 according to the fifth embodiment, except that it includes tunnel layer 9. In this case, first portion 9A of tunnel layer 9 is disposed between second semiconductor region 1E of semiconductor layer 1 and two-dimensional material layer 2 in the vertical direction. First portion 9A is in contact with each of second semiconductor region 1E and two-dimensional material layer 2. In such an electromagnetic wave detector, an effect similar to that of electromagnetic wave detector 104, 105 and electromagnetic wave detector 106 is achieved.

### Seventh Embodiment

FIG. 18 is a cross-sectional view of an electromagnetic wave detector 108 according to a seventh embodiment. As shown in FIG. 18, electromagnetic wave detector 108 basically has a similar configuration and achieves an effect similar to that of electromagnetic wave detector 106 according to the sixth embodiment but differs from electromagnetic wave detector 106 in that tunnel layer 9 is not disposed on unipolar barrier layer 7 and that it further includes a buffer layer 10. In the following, the points of difference from electromagnetic wave detector 106 will mainly be described.

Tunnel layer 9 is not disposed on annular portion 73 of unipolar barrier layer 7 but disposed only inside annular portion 73. The thickness of tunnel layer 9 is equivalent to or smaller than the thickness of unipolar barrier layer 7.

Buffer layer 10 is disposed between two-dimensional material layer 2 and annular portion 73 of unipolar barrier layer 7 in the vertical direction. Buffer layer 10 is disposed, for example, annularly to overlap annular portion 73 in a planar view. The thickness of the entire stack of unipolar barrier layer 7 and buffer layer 10 is larger than the thickness of tunnel layer 9. The material forming buffer layer 10 may be any material that has electrical insulating properties, and contains, for example, at least one selected from the group consisting of metal oxides such as HfO₂ and Al₂O₃, oxides or nitrides of semiconductor such as SiO₂ and Si₃N₄, and BN. The material forming buffer layer 10 may be the same as or different from the material forming tunnel layer 9.

Accordingly, in the interior of opening 6, a step part is formed with tunnel layer 9 and a stack of annular portion 73 of unipolar barrier layer 7 and buffer layer 10. Annular portion 73 of unipolar barrier layer 7 is revealed in the step part.

Two-dimensional material layer 2 is not disposed along a wall surface of the step part formed with tunnel layer 9 and a stack of unipolar barrier layer 7 and buffer layer 10 but spaced apart from the wall surface.

The upper surface of annular portion 73 is in contact with the lower surface of buffer layer 10. The inner peripheral surface of annular portion 73 has a lower region in contact with the outer peripheral surface of tunnel layer 8 and an upper region spaced apart from two-dimensional material layer 2 in a direction along first surface 1A.

The upper surface of tunnel layer 9 has an inner peripheral region in contact with two-dimensional material layer 2 and an outer peripheral region spaced apart from two-dimensional material layer 2 in the vertical direction. The outer peripheral surface of tunnel layer 9 is in contact with inner peripheral surface 7B of annular portion 73.

Buffer layer 10 has an upper surface in contact with two-dimensional material layer 2, a lower surface in contact with annular portion 73, an outer peripheral surface in contact with the side surface of insulating layer 5, and an inner peripheral surface spaced apart from two-dimensional material layer 2 in a direction along first surface 1A.

Accordingly, in electromagnetic wave detector 108, a gap 11 is formed which is surrounded by the outer peripheral region of the upper surface of tunnel layer 9, the upper region of the inner peripheral surface of unipolar barrier layer 7, the inner peripheral surface of buffer layer 10, and the lower surface of two-dimensional material layer 2. The interior of gap 11 is filled with, for example, air or nitrogen (N₂) gas. The interior of gap 11 may be a vacuum.

Annular portion 73 of unipolar barrier layer 7 is not in direct contact with two-dimensional material layer 2. Two-dimensional material layer 2 is electrically connected to annular portion 73 of unipolar barrier layer 7 through gap 11. In unipolar barrier layer 7, the upper end of the side surface of annular portion 73 is closest to two-dimensional material layer 2. The shortest distance between two-dimensional material layer 2 and unipolar barrier layer 7 is the distance between the above upper end of annular portion 73 and two-dimensional material layer 2.

The shortest distance between two-dimensional material layer 2 and annular portion 73 is set to be shorter than the mean free path of photocarriers and such that a photocarrier travels (ballistic transport) between two-dimensional material layer 2 and annular portion 73 opposed to each other with gap 11 interposed. The shortest distance between two-dimensional material layer 2 and annular portion 73 is, for example, 10 nm or less.

The method of manufacturing electromagnetic wave detector 108 differs from the method of manufacturing electromagnetic wave detector 102 in that unipolar barrier layer 7 and buffer layer 10 are formed at step (S2) of forming unipolar barrier layer 7.

At step (S2), for example, after unipolar barrier layer 7 and buffer layer 10 are deposited, unipolar barrier layer 7 and buffer layer 10 are etched using the same mask, whereby unipolar barrier layer 7 and buffer layer 10 are simultaneously formed. At step (S2), the method of depositing unipolar barrier layer 7 and buffer layer 10 includes, for example, but not limited to, a deposition process by ALD, vacuum evaporation, or sputtering, a photolithography process, and an etching process.

<Effect of Electromagnetic Wave Detector 108>

In electromagnetic wave detector 108, two-dimensional material layer 2 is electrically connected to semiconductor layer 1 through unipolar barrier layer 7 and gap 11. An electric field is concentrated on gap 11 that separates the above upper end of unipolar barrier layer 7 and two-dimensional material layer 2 from each other. This field concentration causes ballistic transport between the above upper end of unipolar barrier layer 7 and two-dimensional material layer 2. In a state of being irradiated with an electromagnetic wave with a detection wavelength, photocarriers produced in semiconductor layer 1 are accumulated in unipolar barrier layer 7 and further exhibit ballistic transport from unipolar barrier layer 7 to two-dimensional material layer 2. On the other hand, in the dark state, even when carriers produced by thermal excitation exhibit ballistic transport through gap 11 and reach unipolar barrier layer 7, unipolar barrier layer 7 suppresses flowing of the carriers from two-dimensional material layer 2 into semiconductor layer 1.

For example, when p-type semiconductor layer 1 is irradiated with an electromagnetic wave with a detection wavelength, electrons produced immediately below insulating layer 5 are accumulated in unipolar barrier layer 7 formed as a hole barrier layer and further exhibit ballistic transport from unipolar barrier layer 7 to two-dimensional material layer 2. On the other hand, in the dark state, even when holes produced by thermal excitation exhibit ballistic transport through gap 11 and reach unipolar barrier layer 7, unipolar barrier layer 7 suppresses flowing of the holes from two-dimensional material layer 2 into semiconductor layer 1.

In other words, unipolar barrier layer 7 of electromagnetic wave detector 108 acts in the same manner as unipolar barrier layer 7 of electromagnetic wave detector 100.

Furthermore, in electromagnetic wave detector 108, since unipolar barrier layer 7 and two-dimensional material layer 2 are not in contact with each other, photocarriers are not scattered at the interface between them and can flow into two-dimensional material layer 2. Thus, the photocarrier extraction efficiency of electromagnetic wave detector 108 is higher than the photocarrier extraction efficiency of electromagnetic wave detector 100.

### Eighth Embodiment

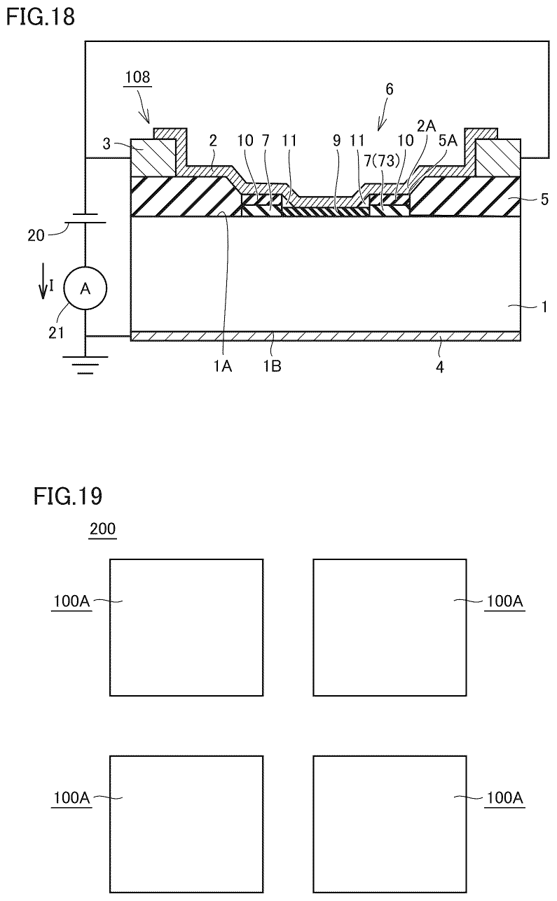

FIG. 19 is a plan view of an electromagnetic wave detector array 200 according to an eighth embodiment. As shown in FIG. 19, electromagnetic wave detector array 200 includes a plurality of detection elements. The detection elements have the same configuration and are each formed with any of the electromagnetic wave detectors according to the first to seventh embodiments. For example, electromagnetic wave detector array 200 includes a plurality of electromagnetic wave detectors 100A according to the first embodiment.

In electromagnetic wave detector array 200, the detection wavelength of each of electromagnetic wave detectors 100A is equal. As shown in FIG. 19, in electromagnetic wave detector array 200, a plurality of electromagnetic wave detectors 100A are disposed in an array in a two-dimensional direction. In other words, a plurality of electromagnetic wave detectors 100A are disposed to be aligned in a first direction and a second direction intersecting the first direction. In electromagnetic wave detector array 200 shown in FIG. 19, four electromagnetic wave detectors 100A are disposed in an array with 2 rows and 2 columns. However, the number of electromagnetic wave detectors 100A disposed is not limited to this. For example, a plurality of electromagnetic wave detectors 100A may be disposed in an array of 3 or more rows and 3 or more columns.

In electromagnetic wave detector array 200 shown in FIG. 19, a plurality of electromagnetic wave detectors 100A are arranged periodically in two dimensions. However, a plurality of electromagnetic wave detectors 100A may be arranged periodically along one direction. The intervals between a plurality of electromagnetic wave detectors 100A may be regular intervals or may be different intervals.

Further, when a plurality of electromagnetic wave detectors 100A are disposed in an array, second electrode part 4 may be a common electrode as long as each individual electromagnetic wave detector 100A can be isolated. Forming second electrode part 4 as a common electrode can reduce wiring of pixels, compared with a configuration in which second electrode part 4 in each electromagnetic wave detector 100A is independent. As a result, the electromagnetic wave detector array can achieve a higher resolution.

In this way, electromagnetic wave detector array 200 including a plurality of electromagnetic wave detectors 100A has a plurality of electromagnetic wave detectors 100A arranged in an array and thereby can be used as an image sensor, a line sensor, or a position sensor for determining a position of an object.

<Modification>

Electromagnetic wave detector array 200 may include a plurality of electromagnetic wave detectors according to any one of the first to seventh embodiments or may include a plurality of electromagnetic wave detectors according to two or more of the first to seventh embodiments.

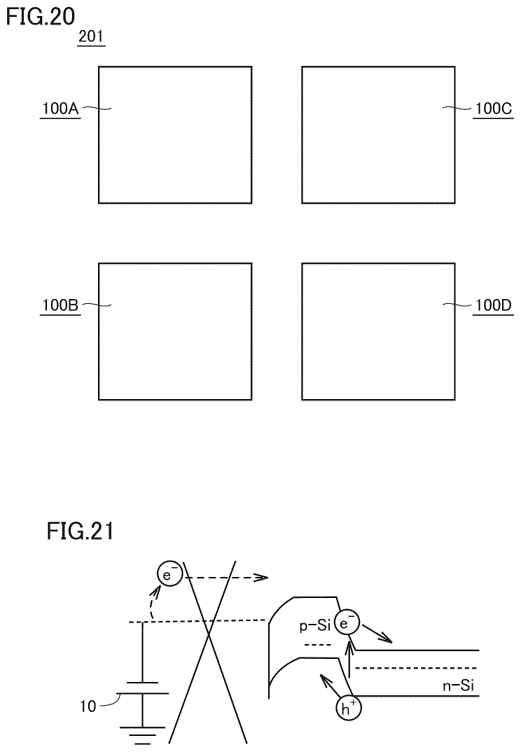

An electromagnetic wave detector array 201 shown in FIG. 20 basically has a configuration similar to electromagnetic wave detector array 200 shown in FIG. 19 and achieves a similar effect but differs from the electromagnetic wave detector array shown in FIG. 19 in that it includes different kinds of electromagnetic wave detectors as a plurality of electromagnetic wave detectors. In other words, in electromagnetic wave detector array 201 shown in FIG. 20, electromagnetic wave detectors of different kinds are disposed in an array (matrix).

In electromagnetic wave detector array 201 shown in FIG. 20, electromagnetic wave detectors of different kinds according to the first to seventh embodiments can be disposed in one-dimensional or two-dimensional array and thereby can be used as an image sensor, a line sensor, or a position sensor for determining a position of an object. Further, the electromagnetic wave detectors included in electromagnetic wave

detector array 201 may be, for example, electromagnetic wave detectors for different detection wavelengths. Specifically, the electromagnetic wave detectors may be prepared as electromagnetic wave detectors according to any of the first to seventh embodiments and having detection wavelength selectivities different from each other. In this case, the electromagnetic wave detector array can detect electromagnetic waves with at least two or more different wavelengths.

A plurality of electromagnetic wave detectors having different detection wavelengths in this way can be disposed in an array to identify a wavelength of an electromagnetic wave in any wavelength range such as wavelength ranges of ultraviolet light, infrared light, terahertz waves, and radio waves, in the same manner as an image sensor for use in the visible light range. As a result, for example, a colored image exhibiting a difference in wavelength as a difference in color can be obtained.

Further, electromagnetic wave detector array 200 may include a not-shown readout circuit configured to read a signal from electromagnetic wave detector 100A.

Electromagnetic wave detector 100A may be disposed on the readout circuit. As a readout format of the readout circuit, a common readout circuit of a visible image sensor can be used. For example, a capacitive transimpedance amplifier (CTIA) type can be used. The readout circuit may employ any other readout format.

Further, electromagnetic wave detector array 200 may include a bump for electrically connecting electromagnetic wave detector 100A and the readout circuit. The structure in which electromagnetic wave detector 100A and the readout circuit are connected by a bump is called hybrid bonding. The hybrid bonding is a common structure in quantum infrared sensors. For example, low-melting-point metal such as In, SnAg, SnAgCu can be used as a material of the bump.

The foregoing embodiments are susceptible to modification and omission if necessary. Furthermore, the foregoing embodiments can be modified in various ways in the implementation phase without departing from their spirit. The foregoing embodiments include inventions in various stages, and various inventions can be extracted depending on an appropriate combination of a plurality of components disclosed.

Embodiments disclosed here should be understood as being illustrative rather than being limitative in all respects. At least two of the embodiments disclosed here can be combined in a consistent manner. The scope of the present disclosure is shown not in the foregoing description but in the claims, and it is intended that all modifications that come within the meaning and range of equivalence to the claims are embraced here.

### REFERENCE SIGNS LIST

1, 1n, 1p semiconductor layer, 1A first surface, 1B second surface, 1C recess, 1D first semiconductor region, 1E second semiconductor region, 2, 2n, 2p two-dimensional material layer, 2A connection part, 3 first electrode part, 4 second electrode part, 5 insulating layer, 5A peripheral part, 6 opening, 7 unipolar barrier layer, 7A outer peripheral surface, 7B inner peripheral surface, 7a electron barrier layer, 7b hole barrier layer, 8, 9 tunnel layer, 9A first portion, 9B second portion, 10 buffer layer, 11 gap, 20 power supply, 21 ammeter, 71, 72 portion, 73 annular portion, 100, 100A, 101, 102, 103, 104, 105, 106, 107, 108 electromagnetic wave detector, 200, 201 electromagnetic wave detector array.

1. An electromagnetic wave detector comprising:
a semiconductor layer;
an insulating layer disposed on the semiconductor layer and having an opening;
a two-dimensional material layer extending from on the opening to on the insulating layer, including a connection part in contact with a peripheral part of the insulating layer facing the opening, and electrically connected to the semiconductor layer;
a first electrode part disposed on the insulating layer and electrically connected to the two-dimensional material layer;
a second electrode part electrically connected to the semiconductor layer; and
a unipolar barrier layer disposed between the semiconductor layer and the connection part of the two-dimensional material layer and electrically connected to each of the semiconductor layer and the two-dimensional material layer,
wherein
the unipolar barrier layer has an annular portion disposed annularly in interior of the opening in a planar view, and
the two-dimensional material layer is in contact with a part of the semiconductor layer positioned inside of the annular portion in a planar view.

2-4. (canceled)

5. The electromagnetic wave detector according to claim 1, wherein
the unipolar barrier layer is disposed on the semiconductor layer, and
the unipolar barrier layer has a tapered section having a thickness gradually reducing as a distance from the peripheral part of the insulating layer increases.

6. The electromagnetic wave detector according to claim 1, wherein
the unipolar barrier layer is buried in interior of the semiconductor layer, and
the peripheral part of the insulating layer is disposed on the unipolar barrier layer.

7. The electromagnetic wave detector according to claim 1, wherein
the semiconductor layer includes a first semiconductor region in contact with the two-dimensional material layer and having a first conductivity type, and a second semiconductor region in contact with the second electrode part and having a second conductivity type different from the first conductivity type, and
the first semiconductor region and the second semiconductor region form a pn junction.

8. An electromagnetic wave detector comprising:
a semiconductor layer;
an insulating layer disposed on the semiconductor layer and having an opening;
a two-dimensional material layer extending from on the opening to on the insulating layer, including a connection part in contact with a peripheral part of the insulating layer facing the opening, and electrically connected to the semiconductor layer;
a first electrode part disposed on the insulating layer and electrically connected to the two-dimensional material layer;
a second electrode part electrically connected to the semiconductor layer; and
a unipolar barrier layer disposed between the semiconductor layer and the connection part of the two-dimensional material layer and electrically connected to each of the semiconductor layer and the two-dimensional material layer, wherein
the unipolar barrier layer has an annular portion disposed annularly in interior of the opening in a planar view,
the electromagnetic wave detector further comprises a tunnel layer having a first portion disposed between a part of the semiconductor layer positioned inside of the annular portion in a planar view and the two-dimensional material layer, and
the two-dimensional material layer is electrically connected to the semiconductor layer by tunnel current flowing through the tunnel layer.

9. The electromagnetic wave detector according to claim 8, wherein the tunnel layer further has a second portion disposed between the annular portion and the two-dimensional material layer.

10. The electromagnetic wave detector according to claim 8, further comprising a buffer layer disposed between the two-dimensional material layer and the annular portion of the unipolar barrier layer in interior of the opening, wherein
a gap is formed between the annular portion of the unipolar barrier layer and the two-dimensional material layer, and
a shortest distance between the annular portion and the two-dimensional material layer is 10 nm or less.

11. The electromagnetic wave detector according to claim 1, wherein
a conductivity type of the semiconductor layer is n-type,
electron affinity and ionization potential of the unipolar barrier layer are smaller than electron affinity and ionization potential of the semiconductor layer, and
a band gap of the unipolar barrier layer is larger than a band gap of the semiconductor layer.

12. The electromagnetic wave detector according to claim 1, wherein
a conductivity type of the semiconductor layer is p-type,
electron affinity and ionization potential of the unipolar barrier layer are larger than electron affinity and ionization potential of the semiconductor layer, and
a band gap of the unipolar barrier layer is larger than a band gap of the semiconductor layer.

13. The electromagnetic wave detector according to claim 1, wherein a material forming the unipolar barrier layer is oxide semiconductor.

14. An electromagnetic wave detector array comprising a plurality of the electromagnetic wave detectors according to claim 1,
wherein the electromagnetic wave detectors are disposed to be aligned along at least one of a first direction and a second direction intersecting the first direction.

15. (canceled)

16. The electromagnetic wave detector according to claim 1, wherein the conductivity type of the two-dimensional material layer is the same as the conductivity type of the semiconductor layer.

17. The electromagnetic wave detector according to claim 1, wherein the conductivity type of the two-dimensional material layer is different from the conductivity type of the semiconductor layer.

18. The electromagnetic wave detector according to claim 1, wherein the unipolar barrier layer has a physical property that does not impede minority carriers in the semiconductor layer from flowing from the semiconductor layer into the two-dimensional material layer, but impedes majority carriers in the semiconductor layer which are produced by thermal excitation in the two-dimensional material layer, from flowing from the two-dimensional material layer into the semiconductor layer.

19. The electromagnetic wave detector according to claim 8, wherein
a conductivity type of the semiconductor layer is n-type,
electron affinity and ionization potential of the unipolar barrier layer are smaller than electron affinity and ionization potential of the semiconductor layer, and
a band gap of the unipolar barrier layer is larger than a band gap of the semiconductor layer.

20. The electromagnetic wave detector according to claim 8, wherein
a conductivity type of the semiconductor layer is p-type,
electron affinity and ionization potential of the unipolar barrier layer are larger than electron affinity and ionization potential of the semiconductor layer, and
a band gap of the unipolar barrier layer is larger than a band gap of the semiconductor layer.

21. The electromagnetic wave detector according to claim 8, wherein a material forming the unipolar barrier layer is oxide semiconductor.

22. An electromagnetic wave detector array comprising a plurality of the electromagnetic wave detectors according to claim 8,
wherein the electromagnetic wave detectors are disposed to be aligned along at least one of a first direction and a second direction intersecting the first direction.
